(19) United States
(12) Patent Application Publication
(10) Pub. No.: US 2016/0074988 A1
(43) Pub. Date: Mar. 17, 2016

(54) PROCESSING MODULE, PROCESSING APPARATUS, AND PROCESSING METHOD

(71) Applicant: EBARA CORPORATION, Tokyo (JP)

(72) Inventors: Kuniaki YAMAGUCHI, Tokyo (JP); Toshio MIZUNO, Tokyo (JP); Itsuki KOBATA, Tokyo (JP)

(21) Appl. No.: 14/849,500

(22) Filed: Sep. 9, 2015

(30) Foreign Application Priority Data
Sep. 11, 2014 (JP) 2014-185515
Aug. 26, 2015 (JP) 2015-166847

(51) Int. Cl. B24B 37/005; B24B 49/12; H01L 21/66; H01L 21/67; H01L 21/306; B24B 49/10; B24B 49/02

(52) U.S. Cl. CPC B24B 37/005; B24B 49/105; B24B 49/12; B24B 49/02; H01L 21/67075; H01L 21/30625; H01L 22/26

(57) ABSTRACT

PROBLEM

An upper treatment module performs polishing treatment by, while bringing a pad smaller in diameter than a wafer into contact with the wafer, relatively moving the wafer and the pad.

MEANS FOR SOLVING

The upper treatment module includes a state detecting section configured to detect states of a polishing treatment surface of the wafer before the polishing treatment or during the polishing treatment and a control section configured to control conditions of the polishing treatment in a portion of the surface of the wafer according to the states of the polishing treatment surface detected by the state detecting section.

### TECHNICAL FIELD

The present invention relates to a treatment module, a treatment apparatus, and a treatment method.

### BACKGROUND ART

In recent years, a treatment apparatus is used to apply various kinds of treatment to a treatment target object (e.g., a substrate such as a semiconductor wafer or various films formed on the surface of the substrate). As an example of the treatment apparatus, there is a CMP (Chemical Mechanical Polishing) apparatus for performing polishing treatment and the like to the treatment target object.

The CMP apparatus includes a polishing unit for performing the polishing treatment of the treatment target object, a cleaning unit for performing cleaning treatment and drying treatment of the treatment target object, and a load/unload unit that delivers the treatment target object to the polishing unit and receives the treatment target object subjected to the cleaning treatment and the drying treatment by the cleaning unit. The CMP apparatus includes a conveying mechanism that performs conveyance of the treatment target object in the polishing unit, the cleaning unit, and the load/unload unit. The CMP apparatus sequentially performs the various kinds of treatment such as polishing, cleaning, and drying while conveying the treatment target object with the conveying mechanism.

### CITATION LIST

### Patent Document

Patent Literature 1: Japanese Patent Application Laid-Open No. 2010-50436

Patent Literature 2: Japanese Patent Application Laid-Open No. 2009-107083

Patent Literature 3: United States Patent No. 2013/0122613

### SUMMARY OF INVENTION

### Technical Problem

Accuracy required of processes in manufacturing of semiconductor devices in recent years has already reached the order of several nanometers. CMP is not an exception. To meet the requirement, optimization of polishing and cleaning conditions is performed in the CMP. However, even if the optimum conditions are determined, changes in polishing and cleaning performance due to control variation of components and aged deterioration of consumable materials are unavoidable. The same applies to a semiconductor wafer itself, which is a treatment target. For example, there are variations of a film thickness of a treatment target film and a device shape before the CMP. These variations become obvious in forms of variations of the residual film and incomplete step elimination during the CMP and after the CMP and in a form of a film remainder in polishing of a film that should originally be completely removed. Such variations occur between chips or traversing the chips in a wafer surface. Further, the variations also occur between wafers and between lots. Under the present situation, to keep these variations within a certain threshold, control of polishing and cleaning conditions for a wafer being polished and a wafer before being polished and rework for a wafer in which the variations exceed the threshold are performed.

However, in the conventional system, the control of the polishing and cleaning conditions and the rework are basically performed by the polishing unit that implements the CMP. In this case, a polishing pad is entirely in contact with the wafer surface in most cases. Even when a portion of the polishing pad is in contact with the wafer surface, a contact area of the polishing pad and the wafer has to be secured large from the viewpoint of maintenance of treatment speed. In such a situation, for example, even if a variation exceeding the threshold occurs in a specific region in the wafer surface, when the variation is corrected by the rework or the like, because of the size of the contact area, the polishing is applied to even a portion for which the rework is unnecessary. As a result, it is difficult to correct the variation to be within an originally requested range of the threshold. Therefore, there is a demand for provision of a method and an apparatus that can apply, with a configuration capable of controlling polishing and cleaning states of a smaller region, retreatment such as control of treatment conditions and rework to any position in a wafer surface.

On the other hand, as another conventional technique, there is known a technique for realizing planarization of a treatment target object by polishing a local projecting portion of a treatment target object using a polishing pad smaller in diameter than the treatment target object. However, this conventional technique is a technique for detecting the projecting portion after applying polishing treatment to the treatment target object. Therefore, it is likely that polishing liquid such as slurry remains on the treatment target object and the projecting portion is not accurately detected. When the projecting portion is not accurately detected, it is likely that planarization by local polishing executed on the basis of a detection result is not accurately executed either.

Therefore, it is at least one object of the present disclosure to realize a treatment module, a treatment apparatus, and a treatment method that can improve treatment accuracy on a polishing treatment surface of a treatment target object.

### Solution to Problem

One embodiment of a treatment module of the present disclosure has been devised in view of the above problems and is a treatment module for performing polishing treatment by, while bringing a pad smaller in diameter than a treatment target object into contact with the treatment target object, relatively moving the treatment target object and the pad, the treatment module including: a state detecting section configured to detect states of a surface of the treatment target object before the polishing treatment or during the polishing treatment; and a control section configured to control conditions of the polishing treatment in a portion of the surface of the treatment target object according to the states of the surface detected by the state detecting section.

In one embodiment of the treatment module, the state detecting section can detect a distribution of a film thickness of the surface of the treatment target object or a signal corresponding to the film thickness, and the control section can control the conditions of the polishing treatment in the portion of the surface of the treatment target object according to the distribution of the film thickness of the surface of the treatment target object or the signal corresponding to the film thickness detected by the state detecting section.

In one embodiment of the treatment module, the state detecting section can include a film-thickness measuring device configured to detect a distribution of a film thickness of the surface of the treatment target object or a signal corresponding to the film thickness before the polishing treatment, and the control section can differentiate the conditions of the polishing treatment in the portion of the surface of the treatment target object from conditions of the polishing treatment in the other portions according to the distribution of the film thickness or the signal corresponding to the film thickness detected by the film-thickness measuring device.

In one embodiment of the treatment module, the state detecting section can include an eddy current sensor or an optical sensor configured to detect a distribution of a film thickness of the surface of the treatment target object during the polishing treatment or a signal corresponding to the film thickness, and the control section can differentiate the conditions of the polishing treatment in the portion of the surface of the treatment target object from conditions of the polishing treatment in the other portions according to the distribution of the film thickness or the signal corresponding to the film thickness detected by the eddy current sensor or the optical sensor.

In one embodiment of the treatment module, the state detecting section can be a film-thickness measuring device configured to detect a distribution of a film thickness or a signal corresponding to the film thickness of the surface of the treatment target after the polishing treatment and cleaning treatment, and the control section can perform the polishing treatment again at the portion of the surface of the treatment target object according to the distribution of the film thickness or the signal corresponding to the film thickness detected by the film-thickness measuring device.

In one embodiment of the treatment module, the state detecting section can further include a film-thickness measuring device configured to detect a distribution of a film thickness of the surface of the treatment target object or a signal corresponding to the film thickness after the polishing treatment, and the control section can change conditions of the polishing treatment in a portion of a treatment target object following the treatment target object, from the conditions of the polishing treatment in the portion of the treatment target object according to the distribution of the film thickness or the signal corresponding to the film thickness detected by the film-thickness measuring device.

In one embodiment of the treatment module, the treatment module can further include a data storage section in which a distribution of a target film thickness of the surface of the treatment target object or a signal corresponding to the target film thickness is stored in advance, and the control section can control the conditions of the polishing treatment in the portion of the surface of the treatment target object based on a difference between the actual distribution of the film thickness of the surface of the treatment target object or the signal corresponding to the film thickness detected by the state detecting section and the distribution of the target film thickness or the signal corresponding to the target film thickness stored in the data storage section.

In the form of the treatment module, the data of polishing amounts for respective conditions of a plurality of kinds of the polishing treatment can be stored in advance in the data storage section, and the control section can control the conditions of the polishing treatment in the portion of the surface of the treatment target object based on the distribution of the film thickness of the surface or the signal corresponding to the film thickness detected by the state detecting section and the data of polishing amounts for the respective conditions of the plurality of kinds of polishing treatment stored in the data storage section.

In one embodiment of the treatment module, the treatment module can further include: a table configured to hold the treatment target object; a head to which the pad is attached; and an arm configured to hold the head, and the treatment module can perform the polishing treatment of the treatment target object by supplying treatment liquid to the treatment target object, rotating the table and the head, bringing the pad into contact with the treatment target object, and swinging the arm.

In one embodiment of the treatment module, the treatment module can further include: a dresser for performing conditioning of the pad; and a dress table for holding the dresser, and the treatment module can perform the conditioning of the pad by rotating the dress table and the head and bringing the pad into contact with the dresser.

One embodiment of a treatment apparatus of the present disclosure includes: a polishing module configured to apply polishing treatment to a treatment target object; any one of the treatment modules described above configured to apply the polishing treatment to the treatment target object; a cleaning module configured to apply cleaning treatment to the treatment target object; and a drying module configured to apply drying treatment to the treatment target object.

One embodiment of a treatment method of the present disclosure is a treatment method for performing polishing treatment by, while bringing a pad smaller in diameter than a treatment target object into contact with the treatment target object, relatively moving the treatment target object and the pad, the treatment method including: a detecting step for detecting states of a surface of the treatment target object before the polishing treatment or during the polishing treatment; and a control step for controlling conditions of the polishing treatment in a portion of the surface of the treatment target object according to the states of the polishing treatment surface detected in the detecting step.

In one embodiment of the treatment method, in the detecting step, a distribution of a film thickness of the surface of the treatment target object or a signal corresponding to the film thickness can be detected, and, in the control step, the conditions of the polishing treatment in the portion of the surface of the treatment target object can be controlled according to the distribution of the film thickness of the surface of the treatment target object or the signal corresponding to the film thickness detected in the detecting step.

In one embodiment of the treatment method, the detecting step can include detecting a distribution of a film thickness of the surface of the treatment target object or a signal corresponding to the film thickness before the polishing treatment, and, in the control step the conditions of the polishing treatment in the portion of the surface of the treatment target object can be differentiated from conditions of the polishing treatment in the other portions according to the distribution of the film thickness or the signal corresponding to the film thickness detected in the detecting step.

In one embodiment of the treatment method, the detecting step can include detecting a distribution of a film thickness of the surface of the treatment target object or a signal corresponding to the film thickness during the polishing treatment, and, in the control step the conditions of the polishing treatment in the portion of the surface of the treatment target object can be differentiated from conditions of the polishing treatment in the other portions, according to the distribution of the film thickness or the signal corresponding to the film thickness detected in the detecting step.

In one embodiment of the treatment method, in the detecting step, a distribution of a film thickness of the surface of the treatment target object or a signal corresponding to the film thickness, subjected to cleaning treatment after being subjected to the polishing treatment can be detected, and, in the control step the portion of the surface of the treatment target object can be subjected to the polishing treatment again according to the distribution of the film thickness or the signal corresponding to the film thickness detected in the detecting step.

In one embodiment of the treatment method, the detecting step can further include detecting a distribution of a film thickness of the surface of the treatment target object or a signal corresponding to the film thickness after the polishing treatment, and, in the control step, conditions of the polishing treatment in a portion of a treatment target object following the treatment target object can be differentiated from conditions of the polishing treatment in the other portions according to the distribution of the film thickness or the signal corresponding to the film thickness detected in the detecting step.

In one embodiment of the treatment method, in the control step, the conditions of the polishing treatment in the portion of the surface of the treatment target object can be controlled based on a difference between the actual distribution of the film thickness of the surface of the treatment target object or the signal corresponding to the film thickness detected in the detecting step and a distribution of a target film thickness set in advance of the surface of the treatment target object or a signal corresponding to the target film thickness.

In one embodiment of the treatment method, in the control step, the conditions of the polishing treatment in the portion of the surface of the treatment target object can be controlled based on the distribution of the film thickness of the surface of the treatment target object or the signal corresponding to the film thickness detected in the detecting step and the data of polishing amounts for respective conditions of a plurality of kinds of polishing treatment stored in the data storage section.

### Advantageous Effects of Invention

According to at least one embodiment of the present disclosure, it is possible to realize a treatment module, a treatment apparatus, and a treatment method that can improve polishing accuracy on a polishing treatment surface of a treatment target object.

### BRIEF DESCRIPTION OF DRAWINGS

FIG. 1 is a plan view showing the overall configuration of a treatment apparatus in an embodiment;

FIG. 2 is a perspective view schematically showing a polishing module;

FIG. 3A is a plan view of a cleaning unit;

FIG. 3B is a side view of the cleaning unit;

FIG. 4 is a diagram showing the schematic configuration of an upper treatment module;

FIG. 5 is a diagram showing the configuration of the upper treatment module 300A in the embodiment;

FIG. 6A is a diagram showing the configuration of the upper treatment module 300A in a first embodiment;

FIG. 6B is a diagram showing the configuration of the upper treatment module 300A in the first embodiment;

FIG. 7 is a flowchart of a treatment method in a first embodiment;

FIG. 8 is a schematic diagram for explaining an example of control by a control section 920;

FIG. 9 is a schematic diagram for explaining an example of the control by the control section 920;

FIG. 10 is a flowchart of a treatment method in a second embodiment;

FIG. 11 is a flowchart of a treatment method in a third embodiment;

FIG. 12 is a diagram showing the configuration of the upper treatment module 300A in a fourth embodiment; and

FIG. 13 is a flowchart of a treatment method in the fourth embodiment.

### DESCRIPTION OF EMBODIMENT

A treatment module, a treatment apparatus, and a treatment method according to an embodiment of the present disclosure are explained below with reference to the drawings.

<Treatment Apparatus>

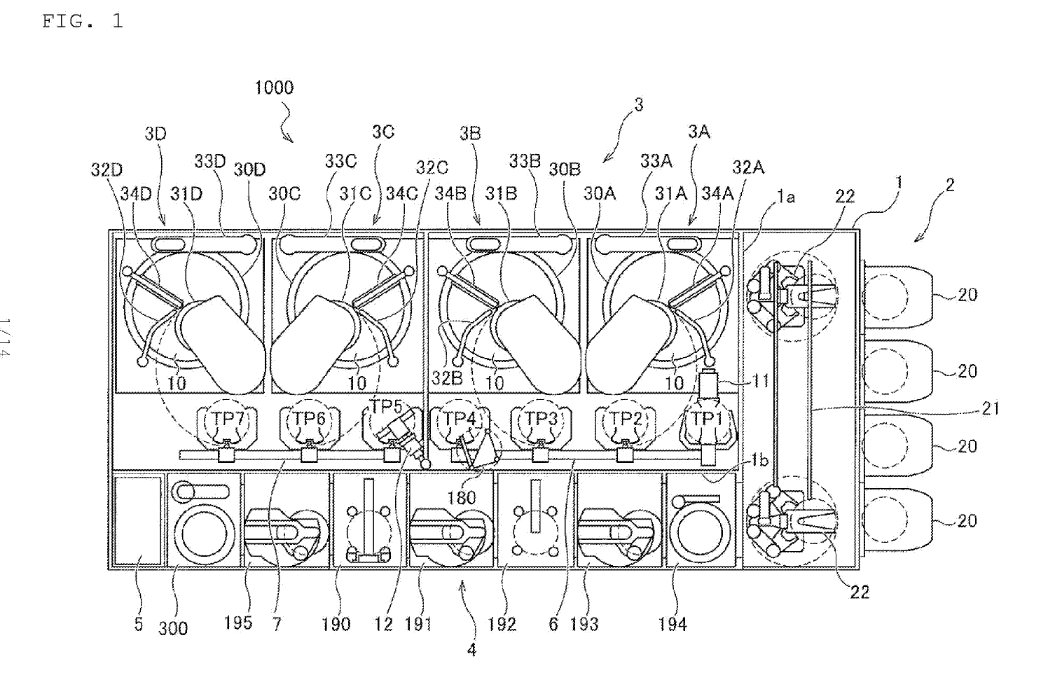

FIG. 1 is a plan view showing the overall configuration of the treatment apparatus according to the embodiment of the present disclosure. As shown in FIG. 1, a treatment apparatus (a CMP apparatus) 1000 for applying treatment to a treatment target object includes a substantially rectangular housing 1. The inside of the housing 1 is partitioned into a load/unload unit 2, a polishing unit 3, and a cleaning unit 4 by partition walls 1a and 1b. The load/unload unit 2, the polishing unit 3, and the cleaning unit 4 are assembled independently from one another and evacuated independently from one another. The cleaning unit 4 includes a power supply section that supplies electric power to the treatment apparatus 1000 and a control device 5 that controls a treatment operation.

<Load/Unload Unit>

The load/unload unit 2 includes two or more (in this embodiment, four) front load sections 20 on which wafer cassettes for stocking a large number of treatment target objects (e.g., wafers (substrates)) are placed. The front load sections 20 are disposed adjacent to the housing 1 and arrayed along a width direction (a direction perpendicular to the longitudinal direction) of the treatment apparatus 1000. On the front load sections 20, open cassettes, SMIF (Standard Manufacturing Interface) pods, or FOUPs (Front Opening Unified Pods) can be mounted. The SMIF and the FOUP are sealed containers that can keep environments therein independent from the outside space by housing the wafer cassettes on the inside and covering the wafer cassettes with partition walls.

In the load/unload unit 2, a traveling mechanism 21 is laid along the array of the front load sections 20. On the traveling mechanism 21, two conveying robots (loaders and conveying mechanisms) 22 movable along an array direction of the wafer cassettes are set. The conveying robots 22 can access the wafer cassettes mounted on the front load sections 20 by moving on the traveling mechanism 21. The conveying robots 22 include hands in upper and lower parts. The upper hands are used when a treated wafer is returned to the wafer cassette. The lower hands are used when a wafer before treatment is taken out from the wafer cassette. In this way, the upper and lower hands can be properly used. Further, the lower hands of the conveying robots 22 are configured to be capable of reversing a wafer.

The load/unload unit 2 is a region that needs to be kept in a cleanest state. Therefore, the inside of the load/unload unit 2 is always maintained at pressure higher than pressures outside the treatment apparatus 1000 and in the polishing unit 3 and the cleaning unit 4. The polishing unit 3 is a dirtiest region because slurry serving as polishing liquid is used. Therefore, a negative pressure is formed on the inside of the polishing unit 3. The pressure is maintained lower than the internal pressure of the cleaning unit 4. In the load/unload unit 2, a filter fan unit (not shown in the figure) including a clean air filter such as an HEPA filter, a ULPA filter, or a chemical filter is provided. Clean air, from which particles, noxious fume, or noxious gas is removed, is always blown out from the filter fan unit.

<Polishing Unit>

The polishing unit 3 is a region where polishing (planarization) of a wafer is performed. The polishing unit 3 includes a first polishing module 3A, a second polishing module 3B, a third polishing module 3C, and fourth polishing module 3D. The first polishing module 3A, the second polishing module 3B, the third polishing module 3C, and the fourth polishing module 3D are arrayed along the longitudinal direction of the treatment apparatus 1000 as shown in FIG. 1.

As shown in FIG. 1, the first polishing module 3A includes a polishing table 30A to which a polishing pad (a polishing tool) 10 having a polishing surface is attached, a top ring 31A for holding a wafer and polishing the wafer while pressing the wafer against the polishing pad 10 on the polishing table 30A, a polishing liquid supply nozzle 32A for supplying polishing liquid and dressing liquid (e.g., pure water) to the polishing pad 10, a dresser 33A for performing dressing of the polishing surface of the polishing pad 10, and an atomizer 34A that jets mixed fluid of liquid (e.g., pure water) and gas (e.g., nitrogen gas) or the liquid (e.g., pure water) to remove slurry and a polishing product on the polishing surface and a pad residue due to the dressing.

Similarly, the second polishing module 3B includes a polishing table 30B, a top ring 31B, a polishing liquid supply nozzle 32B, a dresser 33B, and an atomizer 34B. The third polishing module 3C includes a polishing table 30C, a top ring 31C, a polishing liquid supply nozzle 32C, a dresser 33C, and an atomizer 34C. The fourth polishing module 3D includes a polishing table 30D, a top ring 31D, a polishing liquid supply nozzle 32D, a dresser 33D, and an atomizer 34D.

The first polishing module 3A, the second polishing module 3B, the third polishing module 3C, and the fourth polishing module 3D have the same configuration one another. Therefore, only the first polishing module 3A is explained below.

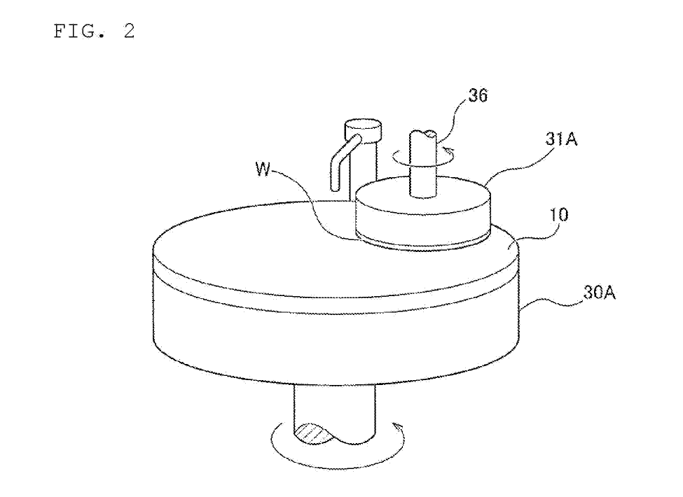

FIG. 2 is a perspective view schematically showing the first polishing module 3A. The top ring 31A is supported by a top ring shaft 36. The polishing pad 10 is stuck to the upper surface of the polishing table 30A. The upper surface of the polishing pad 10 forms a polishing surface for polishing a wafer W. Note that fixed abrasive grains can also be used instead of the polishing pad 10. The top ring 31A and the polishing table 30A are configured to rotate around the axes thereof as indicated by arrows. The wafer W is held on the lower surface of the top ring 31A by vacuum suction. During polishing, in a state in which the polishing liquid is supplied from the polishing liquid supply nozzle 32A to the polishing surface of the polishing pad 10, the wafer W serving as a polishing target is pressed against the polishing surface of the polishing pad 10 by the top ring 31A and polished.

<Conveying Mechanism>

A conveying mechanism for conveying a wafer is explained. As shown in FIG. 1, a first linear transporter 6 is disposed adjacent to the first polishing module 3A and the second polishing module 3B. The first linear transporter 6 is a mechanism that conveys the wafer among four conveying positions (a first conveying position TP1, a second conveying position TP2, a third conveying position TP3, and a fourth conveying position TP4 in order from the load/unload unit side) along a direction in which the polishing modules 3A and 3B are arrayed.

A second linear transporter 7 is disposed adjacent to the third polishing module 3C and the fourth polishing module 3D. The second linear transporter 7 is a mechanism that conveys the wafer among three conveying positions (a fifth conveying position TP5, a fifth conveying position TP6, and a seventh conveying position TP7 in order from the load/unload unit side) along a direction in which the polishing modules 3C and 3D are arrayed.

The wafer is conveyed to the polishing modules 3A and 3B by the first linear transporter 6. The top ring 31A of the first polishing module 3A moves between a polishing position and the second conveying position TP2 according to a swing motion of the top ring head. Therefore, delivery of the wafer to the top ring 31A is performed in the second conveying position TP2. Similarly, the top ring 31B of the second polishing module 3B moves between the polishing position and the third conveying position TP3. Delivery of the wafer to the top ring 31B is performed in the third conveying position TP3. The top ring 31C of the third polishing module 3C moves between the polishing position and the sixth conveying position TP6. Delivery of the wafer to the top ring 31C is performed in the sixth conveying position TP6. The top ring 31D of the fourth polishing module 3D moves between the polishing position and the seventh conveying position TP7. Delivery of the wafer to the top ring 31D is performed in the seventh conveying position TP7.

In the first conveying position TP1, a lifter 11 for receiving the wafer from the conveying robot 22 is disposed. The wafer is passed from the conveying robot 22 to the first linear transporter 6 via the lifter 11. A shutter (not shown in the figure) is provided on the partition wall 1a to be located between the lifter 11 and the conveying robot 22. When the wafer is conveyed, the shutter is opened and the wafer is passed from the conveying robot 22 to the lifter 11. A swing transporter 12 is disposed among the first linear transporter 6, the second linear transporter 7, and the cleaning unit 4. The swing transporter 12 includes a hand movable between the fourth conveying position TP4 and the fifth conveying position TP5. Delivery of the wafer from the first linear transporter 6 to the second linear transporter 7 is performed by the swing transporter 12. The wafer is conveyed to the third polishing module 3C and/or the fourth polishing module 3D by the second linear transporter 7. The wafer polished by the polishing unit 3 is conveyed to the cleaning unit 4 through the swing transporter 12.

<Cleaning Unit>

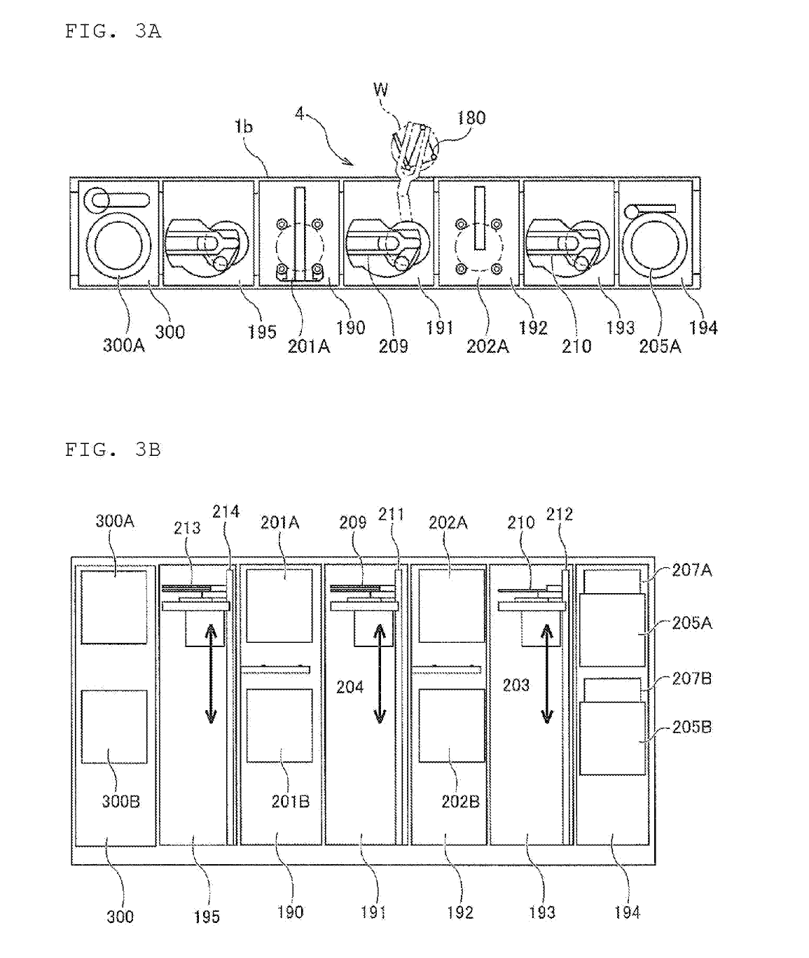

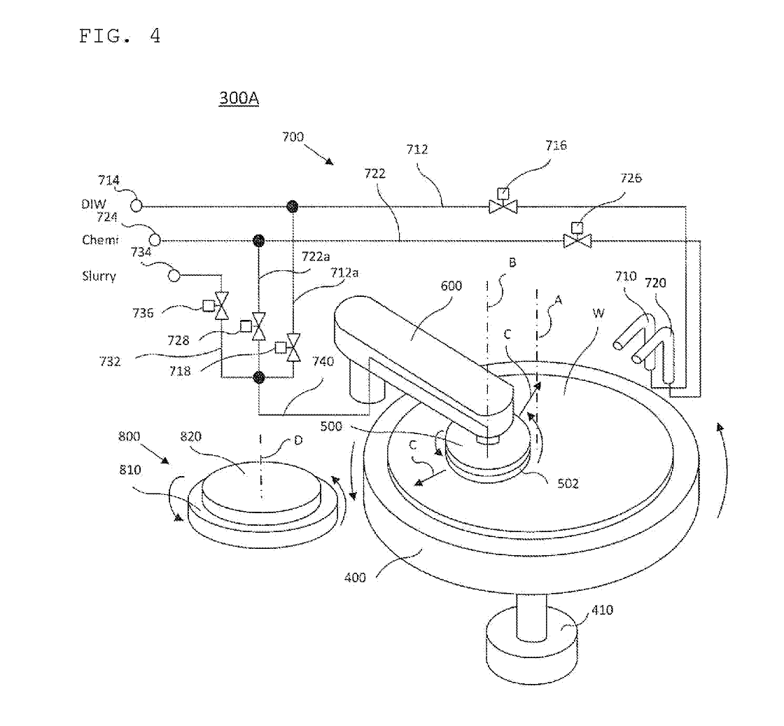

FIG. 3A is a plan view showing the cleaning unit 4. FIG. 3B is a side view showing the cleaning unit 4. As shown in FIGS. 3A and 3B, the cleaning unit 4 is partitioned into a roll cleaning chamber 190, a first conveying chamber 191, a pen cleaning chamber 192, a second conveying chamber 193, a drying chamber 194, a treatment chamber 300, and a third conveying chamber 195. Note that a pressure balance among the polishing unit 3, the roll cleaning chamber 190, the pen cleaning chamber 192, the drying chamber 194, and the treatment chamber 300 can be set in a relation of the drying chamber 194>the roll cleaning chamber 190 and the pen cleaning chamber 192>the treatment chamber 300 the polishing unit 3. The polishing unit 3 uses the polishing liquid. In the treatment chamber 300, the polishing liquid is sometimes used as treatment liquid. Therefore, by setting the pressure balance described above, it is possible to prevent, in particular, inflow of particle components such as abrasive grains in the polishing liquid into the cleaning and drying chambers. Therefore, it is possible to maintain cleanness of the cleaning and drying chambers.

In the roll cleaning chamber 190, an upper roll cleaning module 201A and a lower roll cleaning module 201B arrayed along the longitudinal direction are disposed. The upper roll cleaning module 201A is disposed above the lower roll cleaning module 201B. The upper roll cleaning module 201A and the lower roll cleaning module 201B are cleaning machines that clean the wafer W by pressing rotating two roll sponges (first cleaning tools) respectively against the front and rear surfaces of the wafer W while supplying the cleaning liquid to the front and rear surfaces of the wafer W. A temporary placing table 204 for the wafer W is provided between the upper roll cleaning module 201A and the lower roll cleaning module 201B.

In the pen cleaning chamber 192, an upper pen cleaning module 202A and a lower pen cleaning module 202B arrayed along the longitudinal direction are disposed. The upper pen cleaning module 202A is disposed above the lower pen cleaning module 202B. The upper pen cleaning module 202A and the lower pen cleaning module 202B are cleaning machines that clean the wafer W by pressing a rotating pencil sponge (a second cleaning tool) against the surface of the wafer W and swinging in the radial direction of the wafer W while supplying the cleaning liquid to the surface of the wafer W. A temporary placing table 203 for the wafer W is provided between the upper pen cleaning module 202A and the lower pen cleaning module 202B.

In the drying chamber 194, an upper drying module 205A and a lower drying module 205B arrayed along the longitudinal direction are disposed. The upper drying module 205A and the lower drying module 205B are separated from each other. Above the upper drying module 205A and the lower drying module 205B, filter fan units 207A and 207B that respectively supply clean air into the drying modules 205A and 205B are provided.

The upper roll cleaning module 201A, the lower roll cleaning module 201B, the upper pen cleaning module 202A, the lower pen cleaning module 202B, the temporary placing table 203, the upper drying module 205A, and the lower drying module 205B are fixed to a not-shown frame via bolts or the like.

In the first conveying chamber 191, a first conveying robot (conveying mechanism) 209 movable up and down is disposed. In the second conveying chamber 193, a second conveying robot 210 movable up and down is disposed. In the third conveying chamber 195, a third conveying robot (conveying mechanism) 213 movable up and down is disposed. The first conveying robot 209, the second conveying robot 210, and the third conveying robot 213 are respectively movably supported by supporting shafts 211, 212, and 214 extending in the longitudinal direction. The first conveying robot 209, the second conveying robot 210, and the third conveying robot 213 include driving mechanisms such as motors on the insides and are movable up and down along the supporting shafts 211, 212, and 214. Like the conveying robot 22, the first conveying robot 209 includes hands in upper and lower two stages. As indicated by a dotted line in FIG. 3A, the first conveying robot 209 is disposed in a position where the lower hand thereof can access the temporary placing table 180 described above. When the lower hand of the first conveying robot 209 accesses the temporary placing table 180, the shutter (not shown in the figure) provided on the partition wall 1b opens.

The first conveying robot 209 operates to convey the wafer W among the temporary placing table 180, the upper roll cleaning module 201A, the lower roll cleaning module 201B, the temporary placing table 204, the temporary placing table 203, the upper pen cleaning module 202A, and the lower pen cleaning module 202B. When conveying the wafer W before cleaning (the wafer W to which slurry adheres), the first conveying robot 209 uses the lower hand. When conveying the wafer W after cleaning, the conveying robot 209 uses the upper hand.

The second conveying robot 210 operates to convey the wafer W among the upper pen cleaning module 202A, the lower pen cleaning module 202B, the temporary placing table 203, the upper drying module 205A, and the lower drying module 205B. Since the second conveying robot 210 conveys only the cleaned wafer W, the second conveying robot 210 includes only one handle. The conveying robot 22 shown in FIG. 1 takes out the wafer W from the upper drying module 205A or the lower drying module 205B using the upper hand and returns the wafer W to the wafer cassette. When the upper hand of the conveying robot 22 accesses the drying modules 205A and 205B, the shutter (not shown in the figure) provided on the partition wall 1a opens.

In the treatment chamber 300, an upper treatment module 300A and a lower treatment module 300B are provided. The third conveying robot 213 operates to convey the wafer W among the upper roll cleaning module 201A, the lower roll cleaning module 201B, the temporary placing table 204, the upper treatment module 300A, and the lower treatment module 300B.

Note that, in this embodiment, an example is explained in which, in the cleaning unit 4, the treatment chamber 300, the roll cleaning chamber 190, and the pen cleaning chamber 192 are disposed to be arranged in order from a far side of the load/unload unit 2. However, not only this, but a disposition form of the treatment chamber 300, the roll cleaning chamber 190, and the pen cleaning chamber 192 can be selected as appropriate according to the quality, the throughput, and the like of the wafer W. In this embodiment, an example is explained in which the treatment chamber 300 includes the upper treatment module 300A and the lower treatment module 300B. However, not only this, but the treatment chamber 300 may include only one of the treatment modules. In this embodiment, besides the treatment chamber 300, the roll cleaning module and the pen cleaning module are explained as examples of the module that cleans the wafer W. However, not only this, but two-fluid jet cleaning (2FJ cleaning) or mega sonic cleaning can also be performed. The two-fluid jet cleaning is cleaning for jetting micro droplets (mist) carried on high-speed gas from a two-fluid nozzle toward the wafer W and causing the micro droplets to collide with the wafer W and removing (cleaning) particles and the like on the wafer W surface using a shock wave generated by the collision of the micro droplets on the wafer W surface. The mega sonic cleaning is cleaning for applying ultrasound to the cleaning liquid and causing an action force by vibration acceleration of cleaning liquid molecules to act on adhering grains such as particles to remove the adhering grains. In the following explanation, the upper treatment module 300A and the lower treatment module 300B are explained. The upper treatment module 300A and the lower treatment module 300B have the same configuration. Therefore, only the upper treatment module 300A is explained.

<Treatment Module>

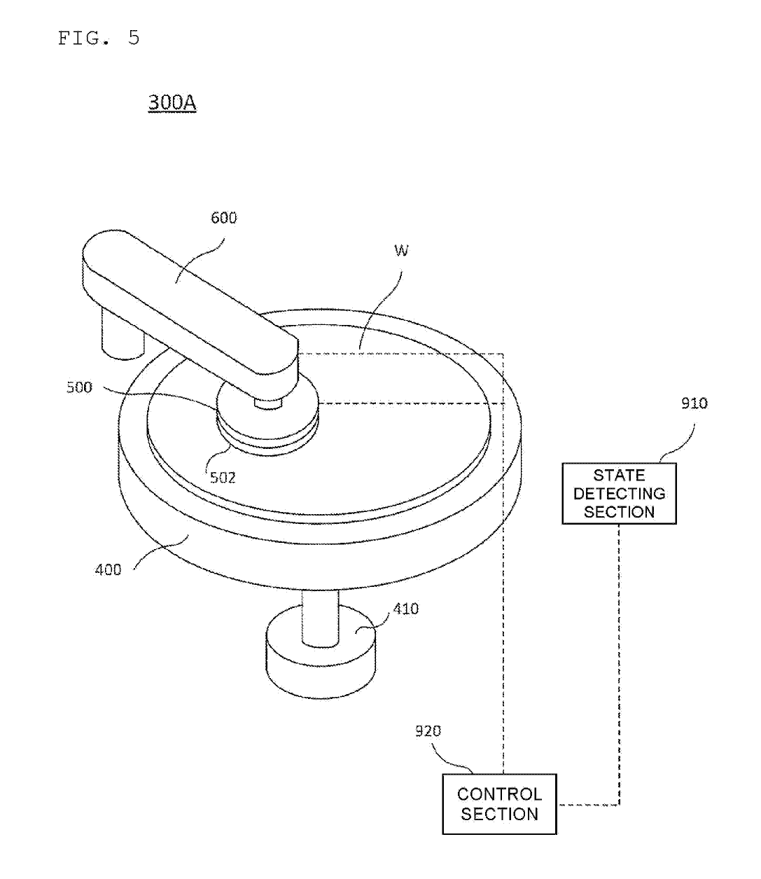

FIG. 4 is a diagram showing the schematic configuration of the upper treatment module. The upper treatment module 300A includes a table 400 on which the wafer W is set, a head 500 to which a pad (a third cleaning tool) 502 for applying treatment to the treatment surface of the wafer W is attached, an arm 600 that holds the head 500, a treatment liquid supply system 700 for supplying the treatment liquid, and a conditioning section 800 for performing conditioning (dressing) of the pad 502. As shown in FIG. 4, the pad (the third cleaning tool) 502 is smaller in diameter than the wafer W. For example, when the wafer W is φ300 mm, the pad 502 is preferably φ100 mm or less and more preferably φ60 to 100 mm. As the diameter of the pad 502 is larger, an area ratio of the pad 502 to the wafer W is smaller. Therefore, treatment speed for the wafer W increases. On the other hand, within wafer non-uniformity of the wafer treatment speed becomes better as the diameter of the pad 502 is smaller. This is advantageous in a system for performing treatment of the entire surface of the wafer W by causing, with the arm 600, the pad 502 to perform a relative motion such as swinging in the surface of the wafer W as shown in FIG. 4. Note that the treatment liquid contains at least one of DIW (pure water), cleaning chemical, and polishing liquid such as slurry. There are mainly two methods of wafer treatment. One is a for removing, at the time of contact with the pad 502, contaminants such as a residue of slurry or a polishing product remaining on the wafer W serving as the treatment target. The other is for removing, through polishing or the like, a fixed amount of the treatment target to which the contaminants adhere. In the former treatment, the treatment liquid is preferably the cleaning chemical or the DIW. In the latter treatment, the polishing liquid is preferable. However, in the latter treatment, for maintenance of a state (flatness and a remaining film amount) of the treatment surface after the CMP, it is desirable that a removal amount in the treatment is, for example, less than 10 nm and preferably 5 nm or less. In this case, removal speed does not need to be as high as removal speed in the normal CMP. In such a case, adjustment of treatment speed may be performed by applying some treatments such as dilution to the polishing liquid as appropriate. The pad 502 is formed of, for example, a foamed polyurethane-based hard pad, a suede-based soft pad, or sponge. In control and rework for a reduction of variation in a wafer surface, it is possible to cope with more various kinds of variations as a contact region of the pad 502 with the wafer W is smaller. Therefore, it is desirable that a pad diameter is small and, more specifically, φ70 mm or less and more preferably φ50 mm or less. The type of the pad 502 only has to be selected as appropriate with respect to the material of a treatment target object and a state of contaminants that should be removed. For example, when the contaminants are buried in the surface of the treatment target object, a hard pad having high hardness and rigidity which a physical force can more easily apply to the contaminants, may be used as the pad 502. On the other hand, when the treatment target object is a material having small mechanical strength such as a Low-k film, a soft pad may be used to reduce damage to the treatment surface. When the treatment liquid is the polishing liquid such as slurry, the slurry may be selected as appropriate. Because removal speed of the treatment target object, removal efficiency of the contaminants, and presence or absence of damage occurrence do not simply depend on only the hardness and the rigidity of the pad 502. A groove shape such as a concentric groove, an XY groove, a spiral groove, or a radial groove may be applied to the surfaces of the pad 502. Further, at least one hole piercing through the pad 502 may be provided in the pad 502 and the treatment liquid may be supplied through the hole. As the pad 502, a sponge-like material, into which the treatment liquid can penetrate, such as PVA sponge may be used. Consequently, it is possible to equalize a flow distribution of the treatment liquid in the pad surface and quickly discharge of the contaminants removed by the treatment.

The table 400 includes a mechanism for sucking the wafer W and holds the wafer W. The table 400 can rotate around a rotation axis A with a driving mechanism 410. The table 400 may cause, with the driving mechanism 410, the wafer W to perform an angular rotational motion or a scroll motion. The pad 502 is attached to a surface of the head 500 opposed to the wafer W. The head 500 can rotate around a rotation axis B with a not-shown driving mechanism. The head 500 can press, with a not-shown driving mechanism, the pad 502 against the treatment surface of the wafer W. The arm 600 can move the head 500 in a range of the radius or the diameter of the wafer W as indicated by an arrow C. The arm 600 can swing the head 500 to a position where the pad 502 is opposed to the conditioning section 800.

The conditioning section 800 is a member for conditioning the surface of the pad 502. The conditioning section 800 includes a dress table 810 and a dresser 820 set on the dress table 810. The dress table 810 can rotate around a rotation axis D with a not-shown driving mechanism. The dress table 810 may cause, with a not-shown driving mechanism, the dresser 820 to perform a scroll motion. The dresser 820 is formed of a diamond dresser in which particles of diamond are electro-deposited on the surface or diamond abrasive grains are disposed on the entire or a part of the contact surface with the pad 502, a brush dresser in which brush bristles made of resin are disposed on the entire or a part of a contact surface with the pad 502, or a combination of the diamond dresser and the brush dresser.

When performing the conditioning of the pad 502, the upper treatment module 300A turns the arm 600 until the pad 502 comes to a position opposed to the dresser 820. The upper treatment module 300A performs the conditioning of the pad 502 by rotating the dress table 810 around the rotation axis D and rotating the head 500 and pressing the pad 502 against the dresser 820. Note that, as conditioning conditions, a conditioning load is preferably set to 80 N or less. When a viewpoint of the life of the pad 502 is taken into account, the conditioning load is more preferably 40 N or less. The pad 502 and the dresser 820 are desirably used at the number of revolutions of 500 rpm or less.

Note that this embodiment indicates an example in which the treatment surface of the wafer W and a dress surface of the dresser 820 are set along the horizontal direction. However, not only this but, for example, in the upper treatment module 300A, the table 400 and the dress table 810 can be disposed such that the treatment surface of the wafer W and the dress surface of the dresser 820 are set along the vertical direction. In this case, the arm 600 and the head 500 are disposed such that the treatment can be performed with the pad 502 set in contact with the treatment surface of the wafer W disposed in the vertical direction and the conditioning treatment can be performed with the pad 502 set in contact with the dress surface of the dresser 820 disposed in the vertical direction. The entire or a part of the arm 600 may rotate such that one of the table 400 and the dress table 810 is disposed in the vertical direction and the pad 502 disposed in the arm 600 is perpendicular to table surfaces.

The treatment liquid supply system 700 includes a pure water nozzle 710 for supplying pure water (DIW) to the treatment surface of the wafer W. The pure water nozzle 710 is connected to a pure water supply source 714 via a pure water pipe 712. An opening and closing valve 716 that can open and close the pure water pipe 712 is provided in the pure water pipe 712. The control device 5 can supply the pure water to the treatment surface of the wafer W at any timing by controlling the opening and closing of the opening and closing valve 716.

The treatment liquid supply system 700 includes a chemical nozzle 720 for supplying chemical to the treatment surface of the wafer W. The chemical nozzle 720 is connected to a chemical supply source 724 via a chemical pipe 722. An opening and closing valve 726 that can open and close the chemical pipe 722 is provided in the chemical pipe 722. The control device 5 can supply the chemical to the treatment surface of the wafer W at any timing by controlling the opening and closing of the opening and closing valve 726.

The upper treatment module 300A can selectively supply the polishing liquid such as pure water, chemical, or slurry to the treatment surface of the wafer W via the arm 600, the head 500, and the pad 502.

That is, a branch pure water pipe 712a branches from between the pure water supply source 714 and the opening and closing valve 716 in the pure water pipe 712. A branch chemical pipe 722a branches from between the chemical supply source 724 and the opening and closing valve 726 in the chemical pipe 722. The branch pure water pipe 712a, the branch chemical pipe 722a, and the polishing liquid pipe 732 connected to the polishing liquid supply source 734 merge into a liquid supply pipe 740. An opening and closing valve 718 that can open and close the branch pure water pipe 712a is provided in the branch pure water pipe 712a. An opening and closing valve 728 that can open and close the branch chemical pipe 722a is provided in the branch chemical pipe 722a. An opening and closing valve 736 that can open and close the polishing liquid pipe 732 is provided in the polishing liquid pipe 732.

A first end portion of the liquid supply pipe 740 is connected to the pipes of the three systems, i.e., the branch pure water pipe 712a, the branch chemical pipe 722a, and the polishing liquid pipe 732. The liquid supply pipe 740 extends through the inside of the arm 600, the center of the head 500, and the center of the pad 502. A second end portion of the liquid supply pipe 740 opens toward the treatment surface of the wafer W. The control device 5 can supply any one of polishing liquids such as pure water, chemical, and slurry or mixed liquid of any combination of the polishing liquids to the treatment surface of the wafer W at any timing by controlling the opening and closing of the opening and closing valve 718, the opening and closing valve 728, and the opening and closing valve 736.

The upper treatment module 300A can apply the treatment to the wafer W by supplying the treatment liquid to the wafer W via the liquid supply pipe 740 and rotating the table 400 around the rotation axis A, pressing the pad 502 against the treatment surface of the wafer W, and swinging the head 500 in the arrow C direction while rotating the head 500 around the rotation axis B. Note that, as conditions in the treatment, although the treatment is basically defect removal by mechanical action, it is desirable that pressure is 3 psi or less and preferably 2 psi or less for a reduction of damage to the wafer W. The number of revolutions of the wafer W and the head 500 is desirably 1000 rpm or less for the uniform distribution of the treatment liquid in the wafer W. Moving speed of the head 500 is 300 mm/sec or less. However, since a distribution of optimum moving speed is different depending on the number of revolutions of the wafer W and the head 500 and the moving distance of the head 500, the moving speed of the head 500 in the wafer W surface is desirably variable. As a system for changing the moving speed in this case, for example, a system that can divide a moving distance in the wafer W surface into a plurality of sections and can set moving speeds in the respective sections is desirable. As a treatment liquid flow rate, a large flow rate is desirable to keep a sufficient distribution in the wafer surface of the treatment liquid even during high-speed rotation of the wafer W and the head 500. However, on the other hand, since an increase in the treatment liquid flow rate causes an increase in treatment costs, the flow rate is desirably 1000 ml/min or less and preferably 500 ml/min or less.

The treatment performed by the upper treatment module 300A includes at least one of polishing treatment and cleaning treatment.

The polishing treatment performed by the upper treatment module 300A is treatment for, while bringing the pad 502 into contact with the wafer W subjected to main polishing treatment by the polishing unit 3, relatively moving the wafer W and the pad 502 and polishing and removing (finish-polishing) the treatment surface of the wafer W by interposing the polishing liquid such as slurry between the wafer W and the pad 502. The polishing treatment performed by the upper treatment module 300A is treatment that can apply, to the wafer W, a physical action force stronger than a physical action force applied to the wafer W by a roll sponge in the roll cleaning chamber 190 and a physical action force applied to the wafer W by a pen sponge in the pen cleaning chamber 192. Removal of a surface layer portion to which contaminants adhere, additional removal of a part that cannot be removed by main polishing in the polishing unit 3, or morphology improvement after the main polishing can be realized by the polishing treatment.

The cleaning treatment performed by the upper treatment module 300A is treatment for, while bringing the pad 502 into contact with the wafer W, relatively moving the wafer W and the pad 502 and removing contaminants on the wafer W surface and improving the treatment surface by interposing cleaning treatment liquid (chemical or chemical and pure water) between the wafer W and the pad 502. The cleaning treatment performed by the upper treatment module 300A is treatment that can apply, to the wafer W, a physical action force stronger than the physical action force applied to the wafer W by the roll sponge in the roll cleaning chamber 190 and the physical action force applied to the wafer W by the pen sponge in the pen cleaning chamber 192.

<Rework and Feedback>

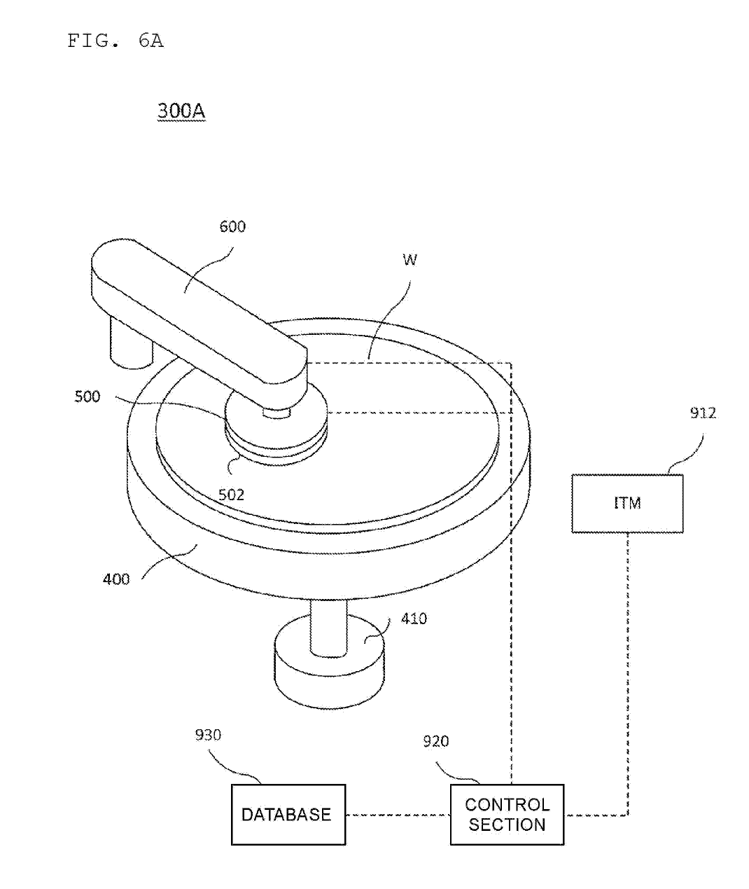

Rework of the wafer W and feedback are explained. FIG. 5 is a diagram showing the configuration of the upper treatment module 300A in the embodiment. Note that, in FIG. 5, to simplify explanation, illustration of components such as the treatment liquid supply system 700 and the conditioning section 800 is omitted.

As shown in FIG. 5, the upper treatment module 300A includes a state detecting section 910 that detects a state of a polishing treatment surface of the wafer W and a control section 920 that controls conditions of polishing treatment in a portion of the surface of the wafer W according to the state of the surface detected by the state detecting section 910.

More specifically, the state detecting section 910 detects a distribution of a film thickness of the surface of the wafer W or a signal corresponding to the film thickness. The control section 920 controls conditions of polishing treatment in the portion of the surface of the wafer W according to the distribution of the film thickness of the surface or the signal corresponding to the film thickness detected by the state detecting section 910. For example, in this case, the control section 920 recognizes that there is a portion where the film thickness is larger than the film thickness in the other portions on the surface of the wafer W, on the basis of the distribution of the film thickness of the polishing treatment surface or the signal corresponding to the film thickness detected by the state detecting section 910. In this case, the control section 920 can control the number of revolutions of the head 500 in the case of contact of the portion having the large film thickness and the pad 502 to be larger than the other portions. The control section 920 may control a pressing force of the head 500 against the wafer W in the case of the contact of the portion having the large film thickness and the pad 502 to be larger than the other portions. The control section 920 may control swinging speed of the arm 600 such that time (polishing time in which the portion having the large film thickness and the pad 502 are in contact is longer than time in which the other portions.

### First Embodiment

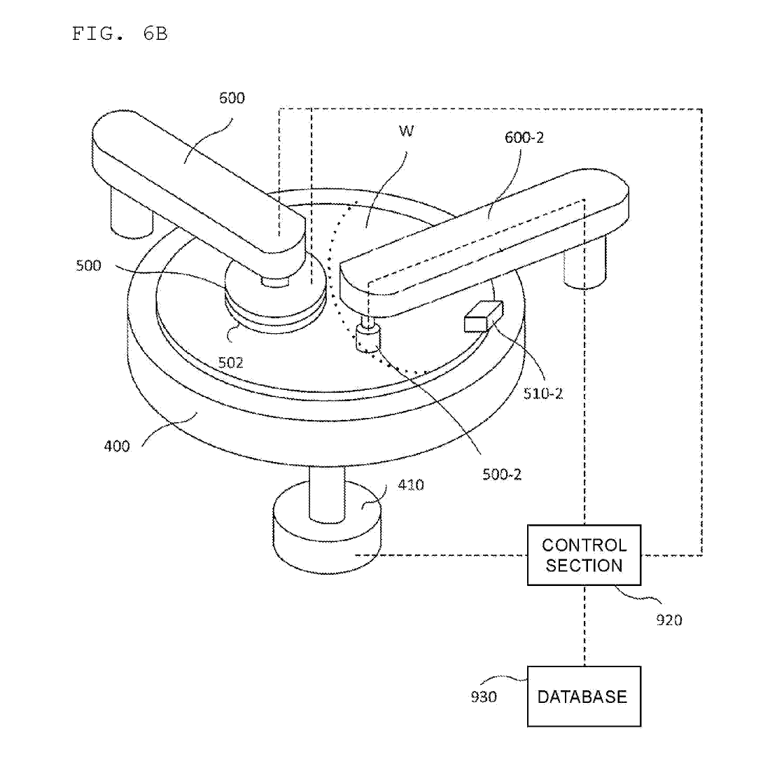

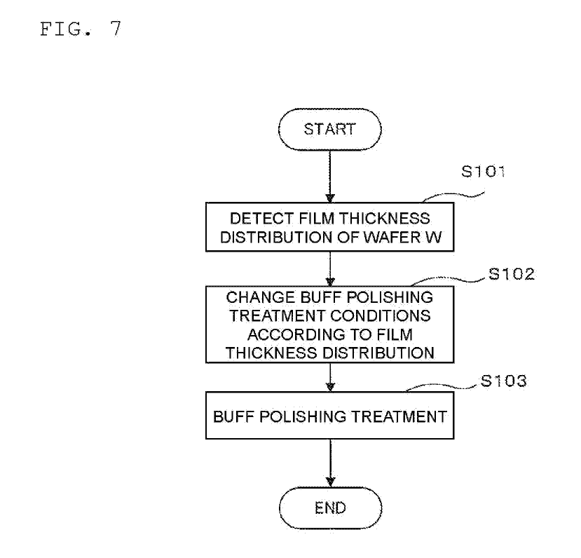

The rework of the wafer W and the feedback are more specifically explained. FIG. 6A is a diagram showing the configuration of the upper treatment module 300A in a first embodiment. Note that, in FIG. 6A, to simplify explanation, illustration of components such as the treatment liquid supply system 700 and the conditioning section 800 is omitted.

As shown in FIG. 6A, the upper treatment module 300A includes a Wet-ITM (In-line Thickness Monitor) 912 as a form of the state detecting section 910. When a detection head is present on the wafer W in a noncontact state and moves over the entire wafer surface, the Wet-ITM 912 can detect (measure) a film thickness distribution of the wafer W (or a distribution of information related to the film thickness). More specifically, the detection head detects the film thickness distribution on the wafer W while moving on a track that passes the center of the wafer W. As a detection system, a noncontact-type detection system such as an eddy current type or an optical type explained below can be adopted. A contact-type detection system may also be adopted. As the contact-type detection system, for example, it is possible to adopt detection of an electric resistance type for preparing a detection head including an energizable probe and, in a state in which the probe is set in contact with the wafer W to energize the probe, causing the probe to scan the inside of the wafer W surface to detect a distribution of film resistance. As another contact-type detection system, it is also possible to adopt a step height detection system for, in a state in which the probe is set in contact with the wafer W surface, causing the probe to scan the inside of the wafer W surface and monitoring up-down movement of the probe to detect a distribution of step height on the surface. In both of the contact-type and noncontact-type detection systems, a detected output is a film thickness or a signal corresponding to the film thickness. In the detection of the optical type, besides a reflected light amount of projected light, a film thickness difference may be recognized from a difference in a color tone on the wafer W surface.

A disposition example of the detection head is shown in FIG. 6B. In this example, a detection head 500-2 is mounted independently of a buff arm 600 in the treatment module 300A. The detection head 500-2 is mounted on an arm 600-2. The arm 600-2 is configured to be swingable in an arcuate shape. Therefore, the detection head 500-2 can move on a track (a dotted line portion) that passes the center of the wafer W. The detection head 500-2 can operate independently of the buff arm 600. The detection head 500-2 is configured to scan the surface of the wafer W to acquire a distribution of a film thickness of the wafer W or a signal related to the film thickness. Note that, in detecting the film thickness of the wafer W, it is desirable to detect the film thickness while rotating the wafer W and while moving the detection head 500-2 in the radial direction. Consequently, it is possible to obtain film thickness information on the entire wafer W surface. Note that, as explained below, a detecting section 510-2 disposed in noncontact with the wafer W, which detects at least one of a notch, an oriental flat, and a laser marker of the wafer W as a reference position may be provided in or outside a treatment module. A rotation angle detecting mechanism may be mounted on the driving mechanism 410 to make it possible to angularly rotate the table 400 from a predetermined position. The detecting section 510-2 is disposed not to rotate together with the table 400. By detecting the position of at least one of the notch, the oriental flat, and the laser marker of the wafer W with the detecting section 510-2, it is possible to associate data such as the film thickness detected by the detection head 500-2 with not only a position in the radial direction but also a position in the circumferential direction. That is, by disposing the wafer W in a predetermined position of the table 400 on the basis of such indexes concerning the positions of the driving mechanism 410 and the wafer W, it is possible to obtain a distribution of a film thickness of the wafer W or a signal related to the film thickness with respect to the reference position. In this example, the detection head 500-2 is mounted independently of the buff arm 600. However, the detection head 500-2 may be attached to the buff arm 600 and configured to acquire the film thickness or the signal related to the film thickness making use of the operation of the buff arm 600. Detection timing is timing before the treatment of the wafer W in this embodiment. However, as explained below, the detection timing may be timing during the treatment or after the treatment. When the detection head 500-2 is independently mounted, the detection head 500-2 does not interfere with the operation of the buff arm 600 before the treatment, after the treatment, or in the interval of the treatment. However, to prevent the detection of the film thickness or the signal related to the film thickness in the treatment of the wafer W from being delayed in time, when the detection of the film thickness of the wafer W is performed simultaneously with the treatment by the buff arm 600, the detection head 500-2 is caused to perform scanning according to the operation of the buff arm 600 during the treatment of the wafer W. Note that, the Wet-ITM is effective in measurement during the treatment implementation. However, in the acquisition of the film thickness or the signal corresponding to the film thickness before the treatment or after the treatment other than during the treatment, the ITM does not always need to be mounted on the treatment module 300A. The ITM may be mounted outside the treatment module, for example, on a load/unload section to implement the measurement when a wafer is inserted into and pulled out from an FOUP or the like. The same applies to the other embodiments explained below.

The upper treatment module 300A includes a database (a data storage section) 930 in which polishing amounts for respective conditions (pressure of the pad 502 on the wafer W, the number of revolutions of the head 500, and a contact time of the pad 502 with the wafer W) of a plurality of kinds of polishing treatment are stored in advance. In the database 930, a target film thickness distribution of the polishing treatment surface of the wafer W is set and stored in advance.

FIG. 7 is a flowchart of a treatment method in the first embodiment. As shown in FIG. 7, first, in the treatment method, a film thickness distribution of the wafer W (or a distribution of a signal corresponding to the film thickness) is detected (measured) using the Wet-ITM 912 (step S101) before the polishing treatment by the upper treatment module 300A.

Subsequently, in the treatment method, according to the distribution of the film thickness of the wafer W or the signal corresponding to the film thickness detected by the Wet-ITM 912, conditions of the polishing treatment in a portion of the surface of the wafer W are differentiated from the other portions using the control section 920 (step S102). For example, the control section 920 controls the table 400, the head 500, or the arm 600 on the basis of the distribution of the film thickness of the wafer W or the signal corresponding to the film thickness detected by the Wet-ITM 912 and the data of polishing amounts for the conditions of the polishing treatment stored in the database 930. The control section 920 can also control the table 400, the head 500, or the arm 600 on the basis of the distribution of the film thickness of the wafer W or the signal corresponding to the film thickness detected by the Wet-ITM 912, the data of polishing amounts for the conditions of the polishing treatment stored in the database 930, and the distribution of the target film thickness or the signal corresponding to the target film thickness.

Subsequently, in the treatment method, the polishing treatment is implemented under the changed polishing treatment conditions (step S103, (feedback)). For example, in this case the control section 920 recognizes that there is a portion where a film thickness is larger than the film thicknesses of the other portions on the polishing treatment surface of the wafer W. In this case, the control section 920 can control the number of revolutions of the head 500 in the case of contact of the portion having the large film thickness and the pad 502 to be larger than the other portions. The control section 920 may control a pressing force of the head 500 against the wafer W in the case of the contact of the portion having the large film thickness and the pad 502 to be larger than the other portions. The control section 920 may control swinging of the arm 600 such that time (polishing time) in which the portion having the large film thickness and the pad 502 are in contact is longer than the other portions. Note that the data obtained by detecting (measuring) the film distribution of the wafer W (or the distribution of the signal corresponding to the film thickness) before the implementation of the polishing treatment by the upper treatment module 300A (S101) may be used for adjusting polishing conditions of the wafer W to be polished by the polishing module the next and subsequent times.

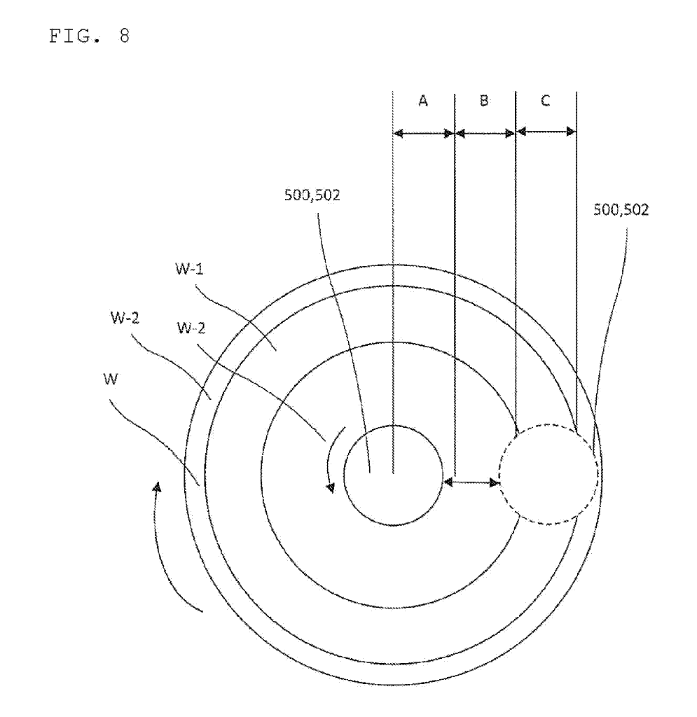

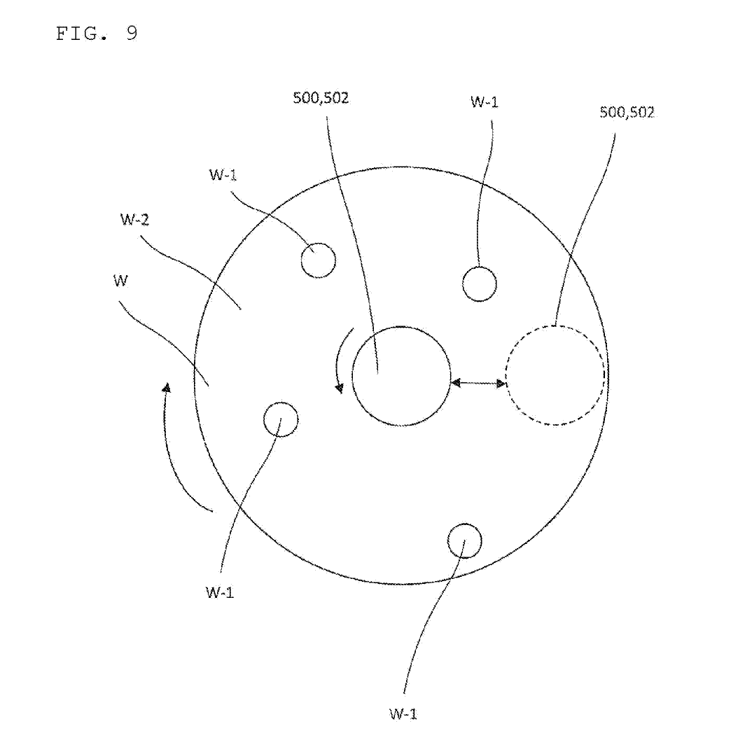

An example of the control by the control section 920 is explained. FIG. 8 is a schematic diagram for explaining the example of the control by the control section 920.

As shown in FIG. 8, in this case, a portion W-1 having a large film thickness compared with the other portions W-2 is distributed in a concentric shape on the surface of the wafer W. In this case, when a swinging range of the head 500 is divided into A, B, and C, the control section 920 can control the head 500 such that the number of revolutions of the head 500 in the swinging range C is large compared with the number of revolutions in the swinging ranges A and B. The control section 920 can control the head 500 such that a pressing force of the pad 502 in the swinging range C is large compared with the pressing force in the swinging ranges A and B. The control section 920 can control swinging speed of the arm 600 such that a polishing time (a staying time of the pad 502) in the swinging range C is long compared with the polishing time in the swinging ranges A and B. Consequently, the control section 920 can polish the polishing treatment surface flat.

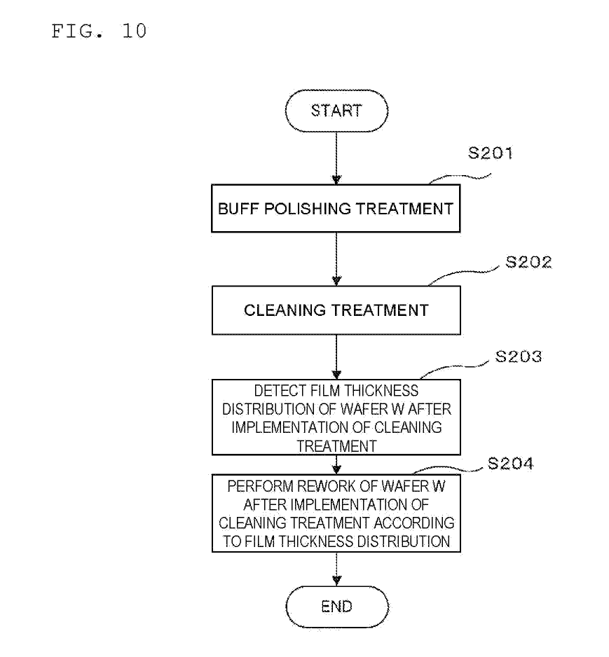

FIG. 9 is a schematic diagram for explaining an example of the control by the control section 920. As shown in FIG. 9, in this case, portions W-1 having a large film thickness compared with the other portion W-2 are distributed at random on the treatment surface of the wafer W. In this case, the control section 920 can control a polishing amount of the portions W-1 having the large film thickness of the wafer W to be larger than a polishing amount of the other portion W-2 by causing the wafer W to perform an angular rotational motion with the driving mechanism 410. For example, the control section 920 can recognize the positions of the portions W-1 having the large film thickness of the wafer W with reference to a notch, an oriental flat, or a laser marker of the wafer W and cause the wafer W to perform the angular rotational motion with the driving mechanism 410 such that the positions are located in the swinging range of the head 500. More specifically, the upper treatment module 300A includes a detecting section 510-2 (see FIG. 6B) that detects at least one of the notch, the oriental flat, and the laser marker of the wafer W. The upper treatment module 300A rotates the wafer W by any predetermined angle such that the notch, the oriental flat, or the laser marker of the wafer W is located in the swinging range of the head 500. Note that, in this example, the detecting section 510-2 for the notch or the like is provided in the treatment module. However, the detecting section 510-2 may be provided outside the treatment module when acquired position information can be referred to in the treatment module even if the detecting section 510-2 is provided outside the treatment module (e.g., when the position of the notch or the like is kept finally at the same position even if a motion such as conveyance is inserted between the detecting section 510-2 and the treatment module). The control section 920 can control the head 500 such that the number of revolutions of the head 500 is large compared with the number of revolutions in the other portion W-2 while the portions W-1 having the large film thickness of the wafer W are located in the swinging range of the head 500. The control section 920 can control the head 500 such that a pressing force of the pad 502 is large compared with the pressing force in the other portions W-2 while the portions W-1 having the large film thickness of the wafer W are located in the swinging range of the head 500. The control section 920 can control swinging speed of the arm 600 such that a polishing time (a staying time of the pad 502) is long compared with the polishing time in the other portion W-2 while the portions W-1 having the large film thickness of the wafer W are located in the swinging range of the head 500. Consequently, the control section 920 can polish the polishing treatment surface flat.

### Second Embodiment

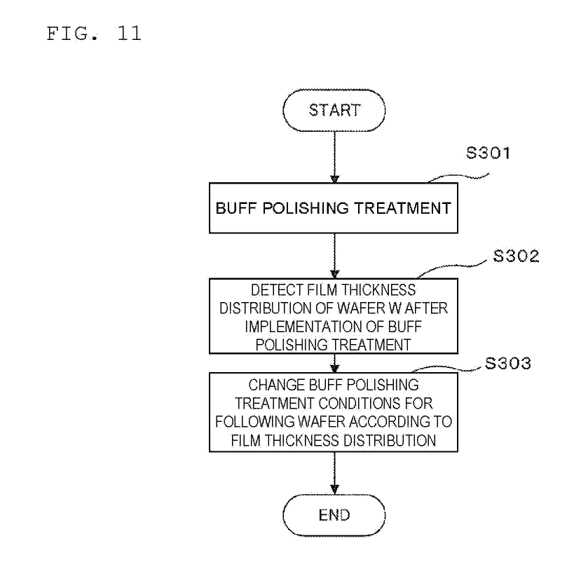

FIG. 10 is a flowchart of a treatment method in a second embodiment. In the treatment method, first, polishing treatment is implemented under predetermined polishing treatment conditions (step S201).

Subsequently, in the treatment method, cleaning treatment is applied to the wafer W (step S202). The cleaning treatment is treatment for cleaning the wafer W with at least one of the upper treatment module 300A, the lower treatment module 300B, the upper roll cleaning module 201A, the lower roll cleaning module 201B, the upper pen cleaning module 202A, and the lower pen cleaning module 202B.

Subsequently, in the treatment method, a film thickness distribution of the wafer W (or a distribution of a signal corresponding to the film thickness) after the cleaning treatment is detected (measured) using the Wet-ITM 912 (S203). Note that, as explained above, concerning an ITM, the Wet-ITM is effective in measurement during the treatment implementation. However, in the acquisition of the film thickness or the signal corresponding to the film thickness before the treatment or after the treatment other than during the treatment, the ITM does not always need to be mounted on the treatment module 300A. The ITM can be mounted outside the treatment module, for example, on a load/unload section to implement the measurement when a wafer is inserted into and pulled out from an FOUP or the like. That is, the Wet-ITM is an ITM for measurement in a non-dry state. Therefore, when the film thickness or the signal corresponding to the film thickness is acquired during the treatment in the upper treatment module 300A, the Wet-ITM is used. On the other hand, when the film thickness or the signal corresponding to the film thickness is acquired in a dry environment before the treatment or after the treatment in the upper treatment module 300A, one of the Wet-ITM and the ITM is used.

Subsequently, in the treatment method, according to the distribution of the film thickness or the signal corresponding to the film thickness detected by the Wet-ITM 912, a portion of the polishing treatment surface of the wafer W, where the distribution of the film thickness or the signal corresponding to the film thickness is detected, is subjected to the polishing treatment again using the control section 920 (step S204 (rework)).

More specifically, in the database 930, a distribution of a target film thickness of the polishing treatment surface of the wafer W or a signal corresponding to the target film thickness is set and stored in advance. The control section 920 can control conditions of the polishing treatment in a portion of the polishing treatment surface of the wafer W on the basis of a difference between the actual distribution of the film thickness of the polishing treatment surface or the signal corresponding to the film thickness detected by the Wet-ITM 912 and the distribution of the target film thickness or the signal corresponding to the target film thickness stored in the database 930. In the database 930, the data of polishing amounts for respective conditions (pressure of the pad 502 on the wafer W, the number of revolutions of the head 500, and a contact time of the pad 502 with the wafer W) of a plurality of kinds of polishing treatment may be stored in advance. In this case, the control section 920 can control the conditions of the polishing treatment in the portion of the polishing treatment surface of the wafer W on the basis of the difference between the actual distribution of the film thickness of the polishing treatment surface or the signal corresponding to the film thickness detected by the Wet-ITM 912 and the distribution of the target film thickness or the signal corresponding to the target film thickness stored in the database 930 and the data of polishing amounts for respective conditions of the plurality of kinds of polishing treatment stored in the database 930.

For example, in this case, after the cleaning treatment is implemented, as shown in FIG. 8, the portion W-1 having the large film thickness compared with the other portions W-2 remains in a concentric shape. In this case, the control section 920 can polish the polishing treatment surface flat by implementing the polishing treatment again in the swinging range C.

For the other example, in this case, after the cleaning treatment is implemented, as shown in FIG. 9, the portions W-1 having the large film thickness compared with the other portion W-2 remain at random. In this case, the control section 920 can recognize the positions of the portions W-1 having the large film thickness of the wafer W with reference to the notch, the oriental flat, or the laser marker of the wafer W and cause the wafer W to perform the angular rotational motion with the driving mechanism 410 such that the positions are located in the swinging range of the head 500. The control section 920 controls the swinging of the arm 600 such that the pad 502 is opposed to the portions W-1 having the large film thickness of the wafer W. The control section 920 can polish the polishing treatment surface flat by implementing the polishing treatment in a state in which the pad 502 is opposed to the portions W-1 having the large film thickness of the wafer W. In particular, in this embodiment, since the film thickness distribution of the wafer W subjected to the cleaning treatment after being subjected to the polishing treatment is detected, the film thickness distribution of the wafer W in a state in which polishing liquid such as slurry used in the polishing treatment is removed. Therefore, according to this embodiment, it is possible to accurately obtain the film thickness distribution of the wafer W. As a result, it is possible to improve accuracy of rework of a polishing surface of the wafer W executed on the basis of the film thickness distribution of the wafer W.

### Third Embodiment

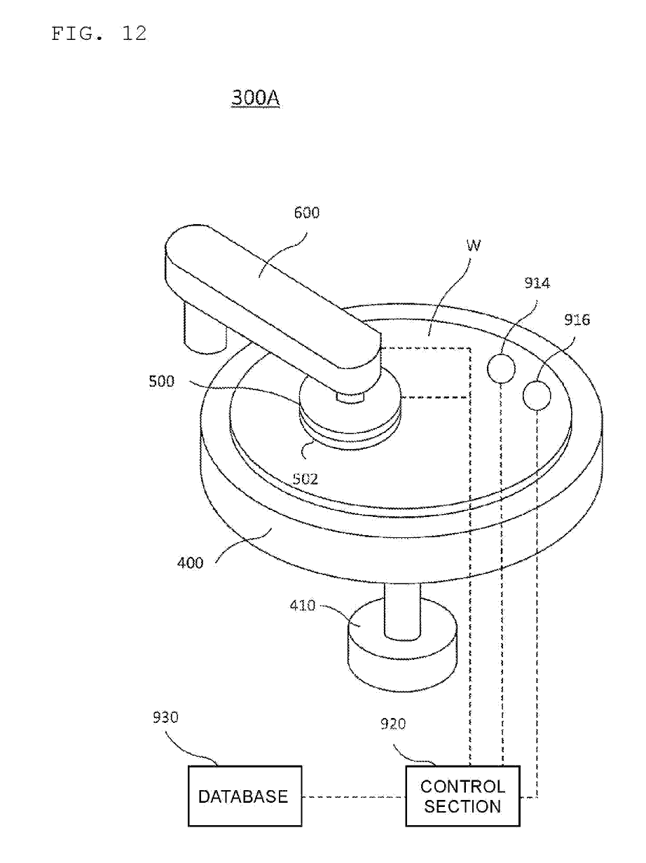

FIG. 11 is a flowchart of a treatment method of a third embodiment. In the treatment method, first, polishing treatment is implemented under predetermined polishing treatment conditions (step S301).

Subsequently, in the treatment method, a film thickness distribution of the wafer W (or a distribution of a signal corresponding to the film thickness) after the polishing treatment by the upper treatment module 300A is detected (measured) using the Wet-ITM 912 (step S302).

Subsequently, in the treatment method, using the control section 920, according to the distribution of the film thickness or the signal corresponding to the film thickness detected by the Wet-ITM 912, conditions of the polishing treatment in a portion of a treatment target object in the treatment of following the wafer W, are changed from the current conditions of the polishing treatment in the portion of the wafer W, where the distribution of the film thickness or the signal corresponding to the film thickness is detected (step S303, (feedback)).

More specifically, in the database 930, a distribution of a target film thickness of the polishing treatment surface of the wafer W or a signal corresponding to the target film thickness is set and stored in advance. The upper treatment module 300A implements the polishing treatment under conditions of first polishing treatment. The control section 920 changes the conditions of the first polishing treatment to conditions of second polishing treatment on the basis of a difference between the actual distribution of the film thickness or the signal corresponding to the film thickness detected by the Wet-ITM 912 and the distribution of the target film thickness or the signal corresponding to the target film thickness stored in the database 930. In the database 930, the data of polishing amounts for respective conditions (pressure of the pad 502 on the wafer W, the number of revolutions of the head 500, and a contact time of the pad 502 with the wafer W) of a plurality of kinds of polishing treatment may be stored in advance. In this case, the control section 920 can change the conditions of the first polishing treatment to the conditions of the second polishing treatment on the basis of the difference between the actual distribution of the film thickness or the signal corresponding to the film thickness detected by the Wet-ITM 912 and the distribution of the target film thickness or the signal corresponding to the target film thickness stored in the database 930 and the data of polishing amounts for respective conditions of the plurality of kinds of polishing treatment stored in the database 930.

For example, in this case, after the polishing treatment is applied to a certain wafer W under the conditions of the first polishing treatment as shown in FIG. 8, the portion W-1 having the large film thickness compared with the other portions W-2 remains in a concentric shape. In this case, it is likely that, similarly, the portion W-1 having the large film thickness tends to remain in the concentric shape on the following wafer W. Therefore, the control section 920 can set the conditions of the second polishing treatment in which the number of revolutions of the head 500 in the swinging range C is large compared with the number of revolutions in the conditions of the first polishing treatment such that the concentric portion W-1 having the large film thickness is not formed on the following wafer W. The control section 920 can set the conditions of the second polishing treatment in which a pressing force of the pad 502 in the swinging range C is large compared with the pressing force in the conditions of the first polishing treatment. The control section 920 can set the conditions of the second polishing treatment in which a polishing time (a staying time of the pad 502) in the swinging range C is long compared with the polishing time in the conditions of the first polishing treatment. Consequently, the control section 920 can polish the polishing treatment surface in the following wafer W flat. Note that, after performing the polishing treatment under the conditions of the second polishing treatment, the control section 920 can repeat steps S301 to 5303 and sequentially change the conditions of the polishing treatment on the basis of the difference between the film thickness distribution detected by the Wet-ITM 912 and the target film thickness distribution stored in the database 930.

### Fourth Embodiment

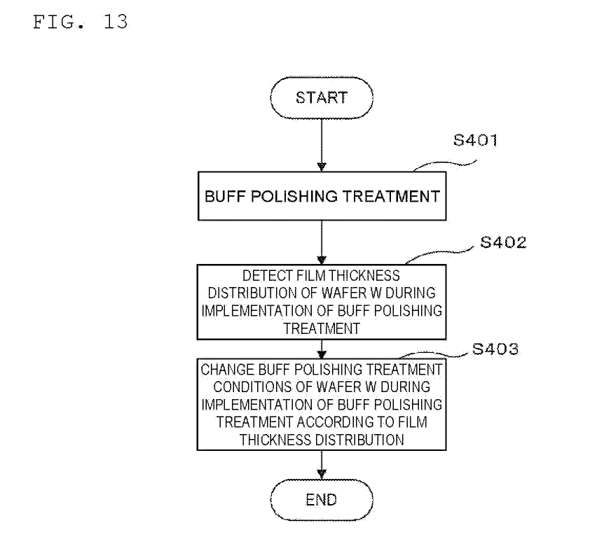

FIG. 12 is a diagram showing the configuration of the upper treatment module 300A in a fourth embodiment. Note that, in FIG. 12, to simplify explanation, illustration of components such as the treatment liquid supply system 700 and the conditioning section 800 is omitted.

As shown in FIG. 12, the upper treatment module 300A includes, as a form of the state detecting section 910, an eddy current sensor 914 and an optical sensor 916 that detect (measure) a film thickness distribution of the polishing treatment surface of the wafer W (or a distribution of a signal corresponding to the film thickness) during the implementation of polishing treatment. Note that, in this embodiment, an example is explained in which the upper treatment module 300A includes both of the eddy current sensor 914 and the optical sensor 916. However, only one of the sensors may be provided.

The eddy current sensor 914 is disposed to be opposed to the polishing treatment surface of the wafer W. The eddy current sensor 914 is a sensor that feeds a high-frequency current to a sensor coil disposed in the vicinity of the polishing treatment surface of the wafer W to generate an eddy current in the wafer W and detects a distribution of a film thickness of the wafer W or a signal corresponding to the film thickness on the basis of a change in the eddy current or combined impedance corresponding to the thickness of the polishing treatment region of the wafer W. The film thickness distribution detected by the eddy current sensor 914 is input to the control section 920.

The optical sensor 916 is disposed to be opposed to the polishing treatment surface of the wafer W. The optical sensor 916 is a sensor that irradiates light toward the polishing treatment surface of the wafer W, receives reflected light reflected on the surface of the wafer W or reflected after being transmitted through the wafer W, and detects a film thickness distribution of the wafer W on the basis of the received reflected light. The distribution of the film thickness or the signal corresponding to the film thickness detected by the optical sensor 916 is input to the control section 920.

FIG. 13 is a flowchart of a treatment method in the fourth embodiment. In the treatment method, first, polishing treatment is implemented under predetermined polishing treatment conditions (step S401).

Subsequently, in the treatment method, a film thickness distribution of the wafer W (or a distribution of information related to the film thickness) during the implementation of the polishing treatment by the upper treatment module 300A is detected (measured) using the eddy current sensor 914 or the optical sensor 916 (step S402). Note that the eddy current sensor 914 and the optical sensor 916 may be fixed independently from each other or fixed to the same arm (e.g., the arm 600-2 shown in FIG. 6B). When the arm moves on the wafer W, the eddy current sensor 914 or the optical sensor 916 may obtain a distribution of a film thickness of the wafer W or a signal corresponding to the film thickness. As another form, the eddy current sensor 914 and the optical sensor 916 may be mounted on the arm 600. When the arm 600 moves, the eddy current sensor 914 and the optical sensor 916 may obtain the distribution of the film thickness of the wafer W or the signal corresponding to the film thickness simultaneously with the movement of the arm 600.

Subsequently, in the treatment method, according to the distribution of the film thickness or the signal corresponding to the film thickness detected by the eddy current sensor 914 or the optical sensor 916, conditions of the polishing treatment in a portion of the polishing treatment surface of the wafer W, where the distribution of the film thickness or the signal corresponding to the film thickness is detected, are differentiated from conditions of the polishing treatment in the other portions using the control section 920 (step S403, (feedback)).

More specifically, in the database 930, a distribution of a target film thickness of the surface of the wafer W or a signal corresponding to the target film thickness is set and stored in advance. The control section 920 can control the conditions of the polishing treatment in the portion of the surface of the wafer W on the basis of a difference between the actual film thickness distribution of the polishing treatment surface detected by the eddy current sensor 914 or the optical sensor 916 and the target film distribution stored in the database 930. In the database 930, the data of polishing amounts for respective conditions (pressure of the pad 502 on the wafer W, the number of revolutions of the head 500, and a contact time of the pad 502 with the wafer W) of a plurality of kinds of polishing treatment may be stored in advance. In this case, the control section 920 can control the conditions of the polishing treatment in the portion of the surface of the wafer W on the basis of the difference between the actual distribution of the film thickness of the polishing treatment surface or the signal corresponding to the film thickness detected by the eddy current sensor 914 or the optical sensor 916 and the distribution of the target film thickness or the signal corresponding to the target film thickness stored in the database 930 and the data of polishing amounts for respective conditions of the plurality of kinds of polishing treatment stored in the database 930. The distribution of the film thickness of the wafer W or the signal corresponding to the film thickness detected by the state detecting section 910 may be transmitted to a host computer (a computer connected to various semiconductor manufacturing apparatuses in a factory to manage the semiconductor manufacturing apparatuses) and accumulated in the host computer. According to a distribution of a film thickness of the wafer W or a signal corresponding to the film thickness transmitted from a polishing apparatus side, the host computer may determine, on the basis of the polishing amounts for the conditions of the polishing treatment stored in a database of the host computer, polishing treatment conditions in a treatment module of the wafer W, where the distribution of the film thickness or the signal corresponding to the film thickness is detected, and transmit the polishing treatment conditions to a control section of the polishing apparatus.

For example, in this case, while the polishing treatment is implemented by the upper treatment module 300A, as shown in FIG. 8, the portion W-1 having the large film thickness compared with the other portions W-2 is distributed in a concentric shape. In this case, the control section 920 can polish the polishing treatment surface flat by controlling the head 500 or the arm 600 such that a polishing amount in the swinging range C is larger than a polishing amount in the swinging ranges A and B.

For example, in this case, while the polishing treatment is implemented by the upper treatment module 300A, as shown in FIG. 9, the portions W-1 having the large film thickness compared with the other portion W-2 are distributed at random. In this case, the control section 920 recognizes the positions of the portions W-1 having the large film thickness of the wafer W with reference to a notch, an oriental flat, or a laser marker of the wafer W. The control section 920 can polish the polishing treatment surface flat by controlling the head 500 or the arm 600 such that, at timing when the portions W-1 having the large thickness of the wafer W is located in the swinging range of the head 500 and opposed to the pad 502, a polishing amount in the portions W-1 is larger than a polishing amount in the other portions.

As explained above, according to the various embodiments of this application, the treatment apparatus includes the state detecting section that detects a state of a polishing treatment surface of a treatment target object and the control section that controls, according to the state of the polishing treatment surface detected by the state detecting section, conditions of polishing treatment in a portion of the polishing treatment surface of the treatment target object. Therefore, it is possible to perform polishing corresponding to the state of the polishing treatment surface of the treatment target object. As a result, according to the various embodiments of this application, it is possible to improve treatment accuracy on the polishing treatment surface of the treatment target object.

### REFERENCE SIGNS LIST

3 Polishing unit

4 Cleaning unit

300 Treatment chamber

300A Upper treatment module

300B Lower treatment module

400 Table

410 Driving mechanism

500 Head

500-2 Detection head

510-2 Detecting section

502 Pad

600 Arm

600-2 Arm

800 Conditioning section

810 Dress table

820 Dresser

910 State detecting section

912 Wet-ITM

914 Eddy current sensor

916 Optical sensor

920 Control section

930 Database (Storing section)

W Wafer

What is claimed is:

1. A treatment module for performing polishing treatment by, while bringing a pad smaller in diameter than a treatment target object into contact with the treatment target object, relatively moving the treatment target object and the pad, the treatment module comprising:
a state detecting section configured to detect states of a surface of the treatment target object before the polishing treatment or during the polishing treatment; and
a control section configured to control conditions of the polishing treatment in a portion of the polishing treatment surface of the treatment target object according to the states of the surface detected by the state detecting section.

2. The treatment module according to claim 1, wherein
the state detecting section is configured to detect a distribution of a film thickness of the surface of the treatment target object or a signal corresponding to the film thickness, and
the control section is configured to control the conditions of the polishing treatment in the portion of the surface of the treatment target object according to the distribution of the film thickness of the surface of the treatment target object or the signal corresponding to the film thickness detected by the state detecting section.

3. The treatment module according to claim 2, wherein
the state detecting section includes a film-thickness measuring device configured to detect a distribution of a film thickness of the surface of the treatment target object or a signal corresponding to the film thickness before the polishing treatment, and
the control section differentiates the conditions of the polishing treatment in the portion of surface of the treatment target object from conditions of the polishing treatment in other portions according to the distribution of the film thickness or the signal corresponding to the film thickness detected by the film-thickness measuring device.

4. The treatment module according to claim 2, wherein
the state detecting section includes one of an eddy current sensor and an optical sensor configured to detect a distribution of a film thickness of the surface of the treatment target object or a signal corresponding to the film thickness or a combination of the sensors during the implementation of the polishing treatment, and
the control section differentiates the conditions of the polishing treatment in the portion of the polishing treatment surface of the treatment target object from conditions of the polishing treatment in other portions according to the distribution of the film thickness detected by the eddy current sensor or the optical sensor.

5. The treatment module according to claim 2, wherein
the state detecting section includes a film-thickness measuring device configured to detect a distribution of a film thickness or a signal corresponding to the film thickness of the surface of the treatment target object after the polishing treatment and the cleaning treatment, and
the control section is configured to perform the polishing treatment again at the portion of the surface of the treatment target object according to the distribution of the film thickness or the signal corresponding to the film thickness detected by the film-thickness measuring device.

6. The treatment module according to claim 2, wherein
the state detecting section further includes a film-thickness measuring device configured to detect a distribution of a film thickness of the surface of the treatment target object or a signal corresponding to the film thickness after the polishing treatment, and
the control section is configured to change conditions of the polishing treatment in a portion of a treatment target object following the treatment target object from the conditions of the polishing treatment in the portion of the treatment target object, according to the distribution of the film thickness or the signal corresponding to the film thickness detected by the film-thickness measuring device.

7. The treatment module according to claim 2, further comprising a data storage section in which a distribution of a target film thickness of the surface of the treatment target object or a signal corresponding to the target film thickness is stored in advance, wherein
the control section is configured to control the conditions of the polishing treatment in the portion of the surface of the treatment target object based on a difference between the actual distribution of the film thickness of the surface of the treatment target object or the signal corresponding to the film thickness detected by the state detecting section and the distribution of the target film thickness or the signal corresponding to the target film thickness stored in the data storage section.

8. The treatment module according to claim 2, wherein
the data of polishing amounts for respective conditions of a plurality of kinds of the polishing treatment are stored in advance in the data storage section, and
the control section is configured to control the conditions of the polishing treatment in the portion of the surface of the treatment target object based on the distribution of the film thickness of the polishing treatment surface or the signal corresponding to the film thickness detected by the state detecting section and the data of polishing amounts for the respective conditions of the plurality of kinds of polishing treatment stored in the data storage section.

9. The treatment module according to claim 1, further comprising:
a table configured to hold the treatment target object;
a head to which the pad is attached; and
an arm configured to hold the head, wherein
the treatment module configured to perform the polishing treatment of the treatment target object by supplying treatment liquid to the treatment target object, rotating the table and the head, bringing the pad into contact with the treatment target object, and swinging the arm.

10. The treatment module according to claim 9, further comprising:
a dresser for performing conditioning of the pad; and
a dress table for holding the dresser, wherein
the treatment module is configured to perform the conditioning of the pad by rotating the dress table and the head and bringing the pad into contact with the dresser.

11. A treatment apparatus comprising:
a polishing module configured to apply polishing treatment to a treatment target object;
the treatment module according to claim 1 configured to apply the polishing treatment to the treatment target object;
a cleaning module configured to apply cleaning treatment to the treatment target object; and
a drying module configured to apply drying treatment to the treatment target object.

12. A treatment method for performing polishing treatment by, while bringing a pad smaller in diameter than a treatment target object into contact with the treatment target object, relatively moving the treatment target object and the pad, the treatment method comprising:
a detecting step for detecting states of a surface of the treatment target object before or during the polishing treatment; and
a control step for controlling conditions of the polishing treatment in a portion of the surface of the treatment target object according to the states of the polishing treatment surface detected in the detecting step.

13. The treatment method according to claim 12, wherein
in the detecting step, a distribution of a film thickness of the surface of the treatment target object or a signal corresponding to the film thickness is detected, and
in the control step, the conditions of the polishing treatment in the portion of the surface of the treatment target object are controlled according to the distribution of the film thickness of the surface of the treatment target object or the signal corresponding to the film thickness detected in the detecting step.

14. The treatment method according to claim 13, wherein
in the detecting step, a distribution of a film thickness of the surface of the treatment target object or a signal corresponding to the film thickness is detected before the polishing treatment, and
in the control step the conditions of the polishing treatment in the portion of the surface of the treatment target object are differentiated from conditions of the polishing treatment in other portions according to the distribution of the film thickness or the signal corresponding to the film thickness detected in the detecting step.

15. The treatment method according to claim 13, wherein
in the detecting step, a distribution of a film thickness of the surface of the treatment target object or a signal corresponding to the film thickness is detected during the polishing treatment, and
in the control step the conditions of the polishing treatment in the portion of the surface of the treatment target object are differentiated from conditions of the polishing treatment in other portions according to the distribution of the film thickness or the signal corresponding to the film thickness detected in the detecting step.

16. The treatment method according to claim 13, wherein
in the detecting step, a distribution of a film thickness of the surface of the treatment target object or a signal corresponding to the film thickness, subjected to cleaning treatment after being subjected to the polishing treatment is detected, and
in the control step the portion of the surface of the treatment target object is subjected to the polishing treatment again according to the distribution of the film thickness or the signal corresponding to the film thickness detected in the detecting step.

17. The treatment method according to claim 13, wherein
in the detecting step, a distribution of a film thickness of the surface of the treatment target object or a signal corresponding to the film thickness is detected after the polishing treatment, and
in the control step, conditions of the polishing treatment in a portion of a treatment target object following the treatment target object are differentiated from conditions of the polishing treatment in other portions according to the distribution of the film thickness or the signal corresponding to the film thickness detected in the detecting step.

18. The treatment method according to claim 13, wherein
in the control step, the conditions of the polishing treatment in the portion of the surface of the treatment target object are controlled based on a difference between the actual distribution of the film thickness of the surface of the treatment target object or the signal corresponding to the film thickness detected in the detecting step and a distribution of a target film thickness set in advance of the surface of the treatment target object or a signal corresponding to the target film thickness.

19. The treatment method according to claim 13, wherein, in the control step, the conditions of the polishing treatment in the portion of the surface of the treatment target object are controlled based on the distribution of the film thickness of the surface of the treatment target object or the signal corresponding to the film thickness detected in the detecting step and the data of polishing amounts for respective conditions of a plurality of kinds of polishing treatment stored in the data storage section.
